(19) United States
(12) Patent Application Publication
(10) Pub. No.: US 2022/0403547 A1
(43) Pub. Date: Dec. 22, 2022

(54) MANUFACTURING APPARATUS FOR GROUP-III COMPOUND SEMICONDUCTOR CRYSTAL

(71) Applicant: Panasonic Holdings Corporation, Osaka (JP)

(72) Inventors: Masayuki HOTEIDA, Osaka (JP); Junichi TAKINO, Osaka (JP); Shunichi MATSUNO, Kyoto (JP)

(21) Appl. No.: 17/837,364

(22) Filed: Jun. 10, 2022

(30) Foreign Application Priority Data
Jun. 21, 2021 (JP) 2021-102689

(51) Int. Cl. C30B 25/14; C30B 25/12; C30B 29/40; C23C 16/30; C23C 16/455; C23C 16/458

(52) U.S. Cl. CPC C30B 25/14; C30B 25/12; C30B 29/406; C23C 16/303; C23C 16/45578; C23C 16/4584

(57) ABSTRACT

The manufacturing apparatus for a group-III compound semiconductor crystal according to the present disclosure comprises a reaction container. The reaction container has a raw material reaction section, a crystal growth section, and a gas flow channel. The raw material reaction section has a raw material reaction chamber, and a raw material gas nozzle. The crystal growth section has a substrate supporting member, and reactive gas nozzles. The gas flow channel includes a first flow channel, a second flow channel, and a connection portion. The first flow channel has a first opening, and the second flow channel has a second opening. The area of the second opening is configured to be larger than the area of the first opening. The connection portion connects the first opening and the second opening with each other. The gas flow channel forms a gas flow path in the reaction container. The substrate supporting member is disposed inside the gas flow path and located on the downstream side of the first opening.

### CROSS-REFERENCE TO RELATED APPLICATIONS

This application claims priority of Japanese Patent Application No. 2021-102689 filed on Jun. 21, 2021, the content of which is incorporated herein by reference.

### BACKGROUND

### 1. Technical Field

The present disclosure relates to a manufacturing apparatus for a group-III compound semiconductor crystal. The present disclosure relates, in particular, to a manufacturing apparatus for a group-III compound semiconductor crystal, using a vapor phase epitaxy method by supplying gas toward a substrate to be processed disposed in a reaction container.

### 2. Description of the Related Art

Group-III compound semiconductors, such as GaN, AlGaN, InGaN, Ga₂O₃, and the like, are used in the fields of, for example, optical devices such as light emitting diodes and semiconductor lasers, and hetero junction high-speed electronic devices. Hydride vapor phase epitaxy (HVPE method) has been practically used as one of the manufacturing methods for GaN that is a group-III compound semiconductor, according to which a group-III elemental metal (such as, for example, Ga metal) and a chloride gas (such as, for example, HCl gas) are reacted with each other to produce a group-III elemental metallic chloride gas (GaCl gas), and GaN is grown from the group-III elemental metallic chloride and a nitrogen element-containing gas (such as, for example, NH₃ gas) (see Japanese Laid-Open Patent Publication No. 52-23600, for example).

With the HVPE method, however, a problem arises that, during the crystal growth, NH₄Cl (ammonium chloride), which is a by-product, is generated in a large amount and clogs a gas discharge pipe of the manufacturing apparatus and blocks the crystal growth. Oxygen vapor phase epitaxy (OVPE method) has been proposed as a method to solve the problem, according to which a group-III elemental metal (such as, for example, Ga metal) and an oxidant (such as, for example, H₂O gas) are reacted with each other to produce a group-III elemental metallic oxide gas (Ga₂O gas) and GaN is grown from the group-III elemental metallic oxide gas and a nitrogen element-containing gas (such as, for example, NH₃ gas) (see, WO2015-053341 for example).

Compared to the growth rate of about 1 μm/h typically acquired in other crystal growth methods such as metalorganic chemical vapor deposition (MOCVD method) and molecular beam epitaxy (MBE method), a feature of the HYPE method and the OVPE method is that an extremely high crystal growth rate of 10 μm/h or higher, or 100 μm/h or higher can be obtained. The HYPE method and the OVPE method are therefore used for manufacturing self-supporting GaN substrates.

FIG. 6 is a schematic cross-sectional diagram depicting a typical cross-sectional structure of an OVPE apparatus as one of the prior art manufacturing apparatuses for a group-III compound semiconductor crystal. The OVPE apparatus includes a reaction container 101 for executing therein the crystal growth of a compound semiconductor. In the reaction container 101, a raw material reaction chamber 102 is disposed to generate therein a group-III element gas, such as Ga₂O. In the raw material reaction chamber 102 heated by first heaters 104, a metal raw material 106 including Ga, In, Al, or the like is accommodated in a raw material container 103. A reactive gas supply pipe 107 supplying a reactive gas such as H₂O gas is connected to the raw material reaction chamber 102. The reactive gas is supplied from the reactive gas supply pipe 107 into the raw material container 103, and a group-III element-containing gas is produced in the raw material reaction chamber 102 by a reaction between the reactive gas and the metal raw material 106. The produced group-III element-containing gas is introduced from a group-III element-containing gas supply pipe 108 connected to the raw material reaction chamber 102 into the reaction container 101, and is conveyed to a seed substrate 112 rested on a substrate supporter 113. The seed substrate 112 is heated by second heaters 105. The reaction container 101 is also provided with nitrogen element-containing gas supply pipes 109a and 109b that supply a nitrogen element-containing gas such as NH₃ gas. The group-III element-containing gas and the nitrogen element-containing gas conveyed to the seed substrate 112 react with each other and a group-III nitride semiconductor crystal 111 is thereby grown on the seed substrate 112.

However, as depicted in FIG. 6, the material gases sprayed from the group-III element-containing gas supply pipe 108 and the nitrogen element-containing gas supply pipes 109a and 109b are supplied to a range that is larger than the area of the substrate supporting part 113, that is, usually to the overall range of the reaction container 101. Therefore, the utilization efficiency of the material gases conveyed to the seed substrate 112 is low. The material gases that have not been conveyed to the seed substrate 112 react with each other, and a sediment including group-III compound semiconductor crystals produced as above adheres to the inner wall surface of the reaction container 101, the inside of the gas discharge pipe, and the like. When particles generated from the sediment mix into the group-III compound semiconductor crystal on the seed substrate 112, dislocations which may block the device operation are concentrated at a high density, and defects on the order of micrometers to millimeters, such as regions called “pit”, through-holes, and the like may be generated. Problems due to these defects will cause a decrease in the yield of a semiconductor device.

### SUMMARY

The present disclosure was conceived in view of the situations, and it is therefore one non-limiting and exemplary embodiment provides a manufacturing apparatus for a group-III compound semiconductor crystal, capable of suppressing the adhesion of sediments to the inner wall surface of the reaction container, and thereby improving the production yield.

A manufacturing apparatus for a group-III compound semiconductor crystal according to the present disclosure comprises a reaction container. The reaction container has a raw material reaction section, a crystal growth section, and a gas flow channel. The raw material reaction section has a raw material reaction chamber that produces therein a group-III element-containing gas, and a raw material gas nozzle that leads the produced group-III element-containing gas out of the raw material reaction chamber, and sprays the produced group-III element-containing gas toward the crystal growth section. The crystal growth section has a substrate supporting member that holds a seed substrate on an upper face thereof and rotates the seed substrate, on which a group-III compound semiconductor crystal grows, and reactive gas nozzles that spray reactive gases for reacting with the group-III element-containing gas to produce the group-III compound semiconductor crystal. The gas flow channel includes a first flow channel which is disposed surrounding a spraying orifice of the raw material gas nozzle and spraying orifices of the reactive gas nozzles, a second flow channel, and a connection portion. The first flow channel has a first opening, and the second flow channel has a second opening. The area of the second opening is configured to be larger than the area of the first opening. The connection portion connects the first opening and the second opening with each other. The gas flow channel forms a gas flow path in which the gases sprayed from both of the raw material gas nozzle and the reactive gas nozzle flow in the reaction container sequentially passing through the first flow channel, the connection portion, and the second flow channel. The substrate supporting member is disposed inside the gas flow path and located on the downstream side of the first opening.

According to the manufacturing apparatus for a group-III compound semiconductor crystal of the present disclosure, the production yield of a group-III compound semiconductor crystal can be improved by suppressing generation of sediments on the inner wall surface of the apparatus on the upstream side of the seed substrate, and suppressing the mixing of particles into the group-III compound semiconductor crystal growing on the seed substrate.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF THE DRAWINGS

The present disclosure will become readily understood from the following description of non-limiting and exemplary embodiments thereof made with reference to the accompanying drawings, in which like parts are designated by like reference numeral and in which:

FIG. 1 is a schematic cross-sectional diagram depicting an example of the configuration of a manufacturing apparatus for a group-III compound semiconductor crystal according to an embodiment of the present disclosure;

FIG. 2A is a front cross-sectional diagram depicting an example of the disposition of a raw material gas nozzle and reactive gas nozzles in the manufacturing apparatus for a group-III compound semiconductor crystal in FIG. 1;

FIG. 2B is a planar diagram depicting an example of the disposition of a raw material gas nozzle and reactive gas nozzles in the manufacturing apparatus for a group-III compound semiconductor crystal in FIG. 1;

FIG. 3 is a schematic cross-sectional diagram depicting the configuration of a manufacturing apparatus for a group-III compound semiconductor crystal according to Comparative Example 1 of the present disclosure;

FIG. 4 is a schematic cross-sectional diagram depicting the configuration of a manufacturing apparatus for a group-III compound semiconductor crystal according to Reference Example 1 of the present disclosure;

FIG. 5A is a photograph of an outer appearance of a GaN substrate grown on a seed substrate according to Example 1 of the present disclosure;

FIG. 5B is a photograph of an outer appearance of a GaN substrate grown on a seed substrate according to Comparative Example 1 of the present disclosure; and

FIG. 6 is a schematic cross-sectional diagram depicting a typical cross-sectional structure of an OVPE apparatus as one of the prior art manufacturing apparatuses for a group-III compound semiconductor crystal.

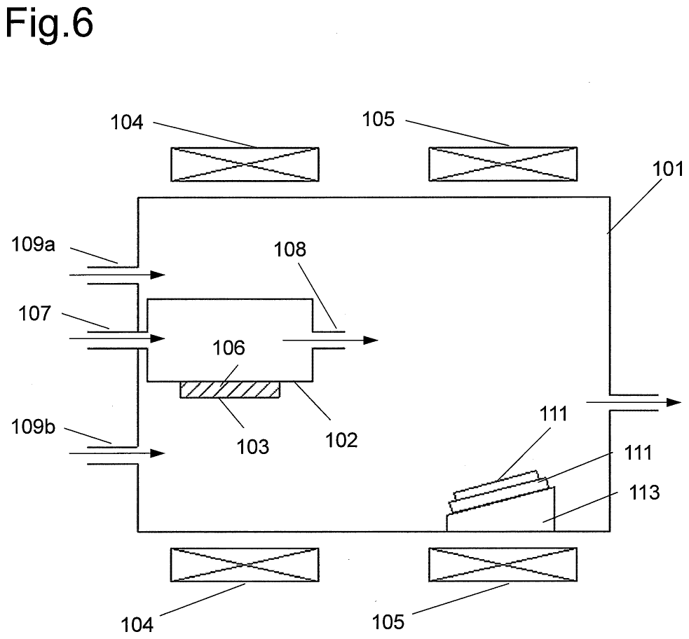

### DETAILED DESCRIPTION

In a first embodiment, a manufacturing apparatus for a group-III compound semiconductor crystal is provided. The manufacturing apparatus comprises a reaction container. The reaction container includes a raw material reaction section, a crystal growth section, and a gas flow channel. The raw material reaction section has a raw material reaction chamber that produces therein a group-III element-containing gas, and a raw material gas nozzle that leads the produced group-III element-containing gas out of the raw material reaction chamber, and sprays the produced group-III element-containing gas toward the crystal growth section. The crystal growth section has a substrate supporting member that holds a seed substrate on an upper face thereof and rotates the seed substrate, on which a group-III compound semiconductor crystal grows, and reactive gas nozzles that spray reactive gases for reacting with the group-III element-containing gas to produce the group-III compound semiconductor crystal. The gas flow channel includes a first flow channel that is disposed surrounding a spraying orifice of the raw material gas nozzle and spraying orifices of the reactive gas nozzles, a second flow channel, and a connection portion. The first flow channel has a first opening, and the second flow channel has a second opening. The area of the second opening is configured to be larger than the area of the first opening. The connection portion connects the first opening and the second opening with each other. The gas flow channel forms a gas flow path in which the gases sprayed from both of the raw material gas nozzle and the reactive gas nozzles flow in the reaction container sequentially passing through the first flow channel, the connection portion, and the second flow channel. The substrate supporting member is disposed inside the gas flow path and located on the downstream side of the first opening.

In one embodiment, a manufacturing apparatus for a group-III compound semiconductor crystal according to the first embodiment is provided, wherein the connection portion is comprised of a tapered shape expanding from the first opening toward the second opening.

In one embodiment, a manufacturing apparatus for a group-III compound semiconductor crystal according to the first embodiment is provided, wherein the substrate supporting member is disposed on the downstream side of the second opening.

In one embodiment, a manufacturing apparatus for a group-III compound semiconductor crystal according to the first embodiment is provided, wherein a difference between the area of the first opening and the area of the upper face of the substrate supporting member is within 30% of the area of the upper face.

In one embodiment, a manufacturing apparatus for a group-III compound semiconductor crystal according to the first embodiment is provided, wherein a difference between an area acquired by subtracting the area of the upper face of the substrate supporting member from the area of the second opening and the area of the first opening is within 50% of the area of the first opening.

In one embodiment, a manufacturing apparatus for a group-III compound semiconductor crystal according to the first embodiment is provided, wherein the first flow channel and the second flow channel are each comprised of a cylindrical shape, and a difference between a vertical distance from the raw material gas nozzle to the upper face of the substrate supporting member and a vertical distance from the spraying orifice of the raw material gas nozzle to the second opening is within 30% of a vertical distance from the raw material gas nozzle to the upper face.

In one embodiment, a manufacturing apparatus for a group-III compound semiconductor crystal according to the first embodiment is provided, wherein the raw material gas nozzle is disposed such that a spraying direction of the spraying orifice thereof is directed toward the upper face of the substrate supporting member.

In one embodiment, a manufacturing apparatus for a group-III compound semiconductor crystal according to the first embodiment is provided, wherein the reactive gas nozzles are disposed such that spraying directions of the spraying orifices thereof are inclined with respect to the upper face of the substrate supporting member.

In one embodiment, a manufacturing apparatus for a group-III compound semiconductor crystal according to the first embodiment is provided, wherein the reactive gas nozzles are disposed such that the spraying directions of the spraying orifices thereof above the upper face of the substrate supporting member are deflected with respect to the radial direction of the rotation of the seed substrate.

Hereinafter, a manufacturing apparatus for a group-III compound semiconductor crystal according to exemplary embodiments of the present disclosure will be described below with reference to the accompanying drawings. In the drawings, members substantially identical to each other are denoted by the same reference numeral.

### EXEMPLARY EMBODIMENTS

### (Manufacturing Apparatus for a Group-III Compound Semiconductor Crystal)

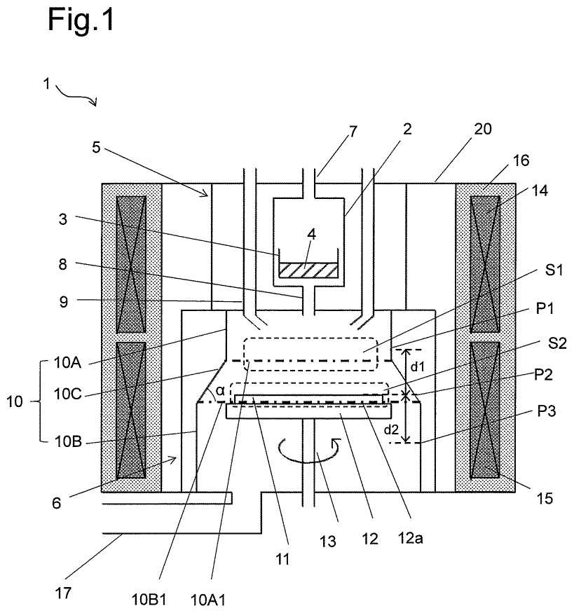

The first embodiment of the present disclosure will be described below with reference to FIG. 1.

FIG. 1 is a schematic cross-sectional diagram depicting an example of the configuration of a manufacturing apparatus 1 for a group-III compound semiconductor crystal according to the embodiment of the present disclosure. In FIG. 1, the sizes, the proportions, and the like of the constituent members may be different from the actual ones.

The manufacturing apparatus 1 for a group-III compound semiconductor crystal according to the embodiment depicted in FIG. 1 is a vapor phase epitaxy apparatus, and includes a reaction container 20 to execute therein crystal growth of a group-III compound semiconductor. The reaction container 20 may have, for example, a cylindrical shape body, and includes a raw material reaction section 5 to generate therein a group-III element-containing gas, a crystal growth section 6, and a gas flow channel 10. The group-III element-containing gas is produced in a raw material reaction chamber 3 which is disposed in the raw material reaction section 5. The produced group-III element-containing gas is led out by a raw material gas nozzle 8, and sprayed toward the crystal growth section 6. In the crystal growth section 6, the group-III element-containing gas sprayed from the raw material gas nozzle 8 and reactive gas introduced by reactive gas nozzles 9 are mixed with each other in a mixing region S1, and thereafter react in a crystal growth region S2 on a seed substrate 11, where a group-III compound semiconductor crystal is grow thereby.

A heating element 16 is disposed on the outer circumferential portion of the reaction container 20 to maintain a constant temperature in the raw material reaction section 5 and the crystal growth section 6. Unreacted raw material gases of the group-III element-containing gas and the reactive gas, as well as carrier gases such as H₂ or N₂ are discharged from a gas outlet 17 disposed on the downstream side of the seed substrate 11.

According to the manufacturing apparatus 1 for a group-III compound semiconductor crystal of the embodiment, generation of sediments on the inner wall surface of the apparatus located on the upstream side of the seed substrate 11 can be suppressed, and mixing of particles into the group-III compound semiconductor crystal growing on the seed substrate can be suppressed.

Constituent members of the manufacturing apparatus 1 for a group-III compound semiconductor crystal according to the embodiment depicted in FIG. 1 will be described below in detail.

### (Raw Material Reaction Section)

Raw material reaction section 5 includes a raw material reaction chamber 2 and a raw material gas nozzle 8. In this embodiment, the raw material reaction section 5 has a cylindrical shape body. Group-III element-containing gases are produced in the raw material reaction section 5.

### (Raw Material Reaction Chamber)

A raw material container 3 accommodating a starting Ga source 4 which is used as a group-III element-containing source is disposed in the raw material reaction chamber 2. The raw material reaction chamber 2 is connected to a reactive gas supply pipe 7, and the reactive gas to react with the starting Ga source is introduced into the raw material reaction chamber 2 by the reactive gas supply pipe 7. The temperature inside of the raw material reaction chamber 2 is maintained to be a desired temperature by a first heater 14 of a heating element 16. It is preferred that the starting Ga source 4 and the reactive gas react with each other in the raw material reaction chamber 2 which is maintained to be at 900° C. or higher and 1,300° C. or lower by the first heater 14 to produce group-III element-containing gases.

Methods for producing group-III element-containing gases include a method of oxidizing a group-III element-containing source and a method of reducing a group-III element-containing source.

A reaction system, in which metallic Ga is used as the starting Ga source 4 and oxidizing gas H₂O is used as a reactive gas, is described as the method of oxidizing a group-III element-containing source. In this case, as expressed in formula (1) below, in the state where heating is executed, the introduced H₂O gas reacts with the metal Ga to produce group-III element-containing gas G₂O.

2Ga+H₂O→Ga₂O+H₂

In addition to Ga, Al, In, and the like are also usable as group-III element-containing sources. In the case with any of the above, a group-III oxide gas is produced.

A reaction system, in which Ga₂O₃ is used as the starting Ga source 4 and reducing gas H₂ is used as a reactive gas, is described as the method of reducing a group-III element-containing source. As expressed in formula (2) below, in the state where heating is executed, the introduced H₂ gas reacts with Ga₂O₃ to produce group-III element-containing gas Ga₂O.

Ga₂O₃+2H₂→Ga₂O+2H₂O

In addition to Ga₂O₃, Al₂O₃, In₂O₃, and the like are also usable as group-III element-containing sources. In the case with any of the above, a group-III oxide gas is produced.

Inert gases, such as Ar or N₂, or H₂ gas, can be used as carrier gases for oxidizing gases or reducing gases.

### (Raw Material Gas Nozzle)

The group-III element-containing gas produced in the raw material reaction chamber 2 such as, for example, the Ga₂O gas is led out by the raw material gas nozzle 8 disposed on the downstream side of the raw material reaction section 5, and sprayed toward the crystal growth section 6. The raw material gas nozzle 8 can be provided with separate gas discharge outlets disposed on the inner circumference or the outer circumference thereof to suppress the adhesion of sediments including group-III compound semiconductor crystals to the inner wall surface of the manufacturing apparatus 1. It is not limited to, but inert gases such as Ar or N₂, or H₂ gas can be used as the separate gas. The inner diameter of the raw material gas nozzle 8 is preferably more than 0 mm and 100 mm or smaller, and is more preferably 20 mm or larger and 60 mm or smaller, but not limited to. The thickness of the raw material gas nozzle 8 is preferably 0.5 mm or larger and 10 mm or smaller, and is more preferably 1 mm or larger and 3 mm or smaller, but not limited to.

### (Crystal Growth Section)

The crystal growth section 6 includes a substrate supporting member 12 and reactive gas nozzles 9. In this embodiment, the crystal growth section 6 has a cylindrical shape body. In the crystal growth section 6, group-III element-containing gas and reactive gas (nitrogen element-containing gas or oxygen element-containing gas) react with each other, and group-III compound semiconductor crystals grow on the seed substrate.

### (Substrate Supporting Member)

The substrate supporting member 12 may be, for example, a substrate susceptor. The seed substrate 11 is supported on the upper face 12a of the substrate supporting member 12. The shape of the substrate supporting member 12 is not limited to, but can be configured not to have a structure that inhibits crystal growth. For example, if a structure on which crystals may grow is present near the crystal growth surface on the seed substrate 11, a circulating flow may generate and sediments may adhere to the structure, which deteriorate the uniformity of the group-III compound semiconductor crystal film on the seed substrate 11. In this embodiment, the seed substrate 11 and the substrate supporting member 12 each have a circular shape. For the material of the substrate supporting member 12, for example, ceramic such as carbon, SiC-coated carbon, PG-coated carbon, PBN-coated carbon, or SiC, or molybdenum, iron, cobalt, nickel, or alloys containing any of these as the main components, are usable.

The substrate supporting member 12 is connected to a rotating shaft 13, by which the seed substrate 11 can be rotated during the growth of group-III compound semiconductor crystals. Preferably, the rotating shaft 13 has a mechanism capable of controlling rotations up to 3,000 rpm.

### (Reactive Gas Nozzle)

The reactive gas nozzles 9 spray reactive gas (such as nitrogen element-containing gas or oxygen element-containing gas) toward the seed substrate 11 to react with the group-III element-containing gas for producing a group-III compound semiconductor crystal. In the manufacturing apparatus 1 for a group-III compound semiconductor crystal depicted in FIG. 1, the reactive gas nozzles 9 include at least two or more reactive gas nozzles 9, which can be arranged, for example, in a radial fashion with respect to the center of the substrate supporting member 12, but it is not limited to. To improve the mixing of the group-III element-containing gas sprayed from the raw material gas nozzle 8 and the reactive gas sprayed from the reactive gas nozzles 9, the spraying direction of each of the reactive gas nozzles 9 can intersect the spraying direction of the raw material gas nozzle 8 at a position in front of the upstream side of the seed substrate 11 in a front view and a top view of the upper face 12a of the substrate supporting member 12.

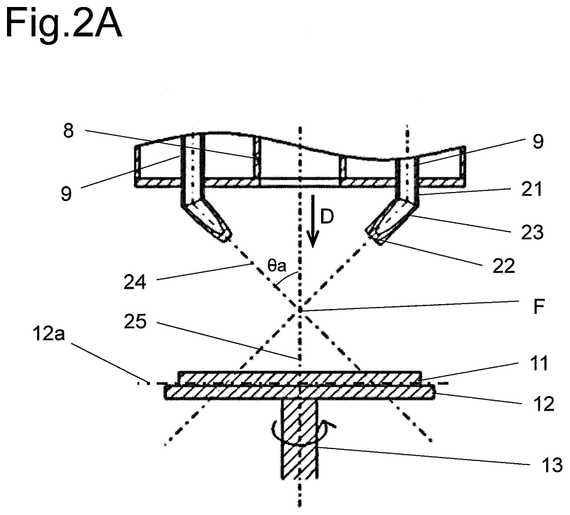

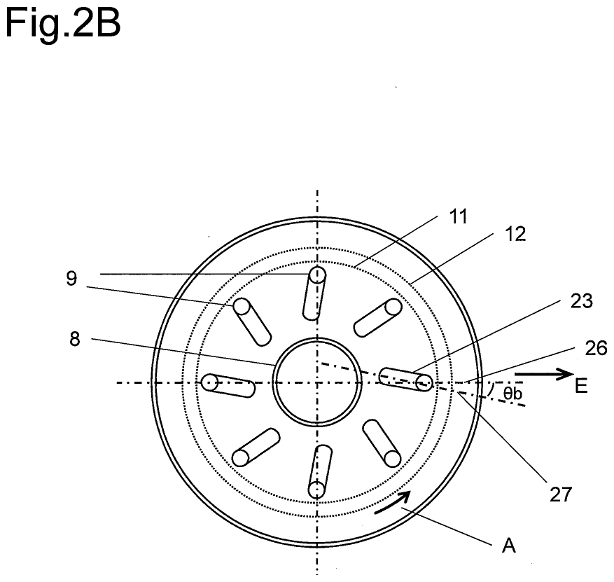

FIG. 2A is a front cross-sectional diagram depicting an example of the disposition of a raw material gas nozzle and reactive gas nozzles in the manufacturing apparatus for a group-III compound semiconductor crystal in FIG. 1. FIG. 2B is a planar diagram depicting an example of the disposition of a raw material gas nozzle and reactive gas nozzles in the manufacturing apparatus for a group-III compound semiconductor crystal in FIG. 1. As depicted in FIG. 2A, the spraying direction of the spraying orifice of the raw material gas nozzle 8 is directed to the upper face 12a of the substrate supporting member along a straight line direction D. The reactive gas nozzles 9 each include a main body 21, and a tip portion 23 which has a spraying orifice 22. The tip portion 23 is inclined at an inclination angle θa with respect to the direction D. In the front view of FIG. 2A, a virtual line 24 along the spraying direction of each of the reactive gas nozzles 9 and a virtual line 25 along the spraying direction of the raw material gas nozzle 8 intersect each other at a position F located above the substrate supporting member 12. The inclination angle θa is the angle formed by the spraying directions of the raw material gas nozzle 8 and each of the reactive gas nozzles 9 in a vertical plane with respect to the upper face 12a of the substrate supporting member.

As depicted in FIG. 2B, the manufacturing apparatus 1 for a group-III compound semiconductor crystal includes at least two or more reactive gas nozzles 9. In this embodiment, as depicted in the planar view in FIG. 2B, the at least two or more reactive gas nozzles 9 are arranged in a radial fashion with respect to the center of the substrate supporting member 12. The tip portion 23 of each of the reactive gas nozzles 9 is inclined at a deflection angle θb with respect to a radial direction E above the upper face 12a of the substrate supporting member. The deflection angle θb is the angle formed by the central axial direction 27 of the tip portion 23 of each of the reactive gas nozzles 9 and the radial direction 26 of the seed substrate 11 in the planar view of FIG. 2B.

In this embodiment, each of the reactive gas nozzles 9 is disposed such that, in the planar view of FIG. 2B, when a reactive gas nozzle 9 self-rotates by the deflection angle θb in the forward direction of a rotation direction A of the substrate supporting member 12, the reactive gas nozzle 9 is directed in the radial direction of the upper face 12a of the substrate supporting member. The reactive gas sprayed by the plural reactive gas nozzles 9 can form a swirling flow, and thereby the mixing of the reactive gas with the group-III element-containing gas can be enhanced. The spraying direction of each of the plural reactive gas nozzles 9 is not limited to the above. For example, each of the plural reactive gas nozzles 9 may be disposed being deflected in the direction opposite to that as shown in FIG. 2B.

In the crystal growth section 6, a crystal of a group-III compound semiconductor such as GaN or Ga₂O₃ can be grown on the seed substrate 11. In the case when a GaN crystal is grown, nitrogen element-containing gas such as NH₃ gas, NO gas, NO₂ gas, N₂H₂ gas, or N₂H₄ gas can be used. In the case when a Ga₂O₃ crystal is grown, oxygen element-containing gas such as O₂ gas or H₂O₂O gas can be used. Similar to the raw material gas nozzle 8, the reactive gas nozzles 9 can be provided with separate gas discharge outlets disposed on the inner circumference or the outer circumference thereof to suppress the adhesion of sediments including group-III compound semiconductor crystals to the inner wall surface of the manufacturing apparatus 1. It is not limited to, but inert gases such as Ar or N₂, or an H₂ gas can be used as the separate gas.

The inner diameter of each of the reactive gas nozzles 9 is not limited, but preferably is more than 0 mm and 30 mm or smaller, and more preferably is in a range from 3 mm to 15 mm. The inclination angle θa of each of the reactive gas nozzles 9 is not limited, but preferably is more than 0 degree and smaller than 90 degrees, and more preferably is in a range from 5 degrees to 60 degrees. The deflection angle θb of each of the reactive gas nozzles 9 is not limited, but preferably is more than 0 degree and smaller than 90 degrees, and more preferably is in a range from 5 degrees to 45 degrees.

To promote the generation of the group-III compound semiconductor crystal in the crystal growth region S2, the reactive gas nozzles 9 can be heated to establish a state in which the nitrogen element-containing gas or the oxygen element-containing gas in the reactive gas nozzles 9 is decomposed at a predetermined ratio. In this embodiment, similar as the raw material reaction chamber 2, the reactive gas nozzles 9 are heated by the first heater 14 of the heating element 16 disposed in the outer circumferential portion of the reactive gas nozzles 9.

### (Gas Flow Channel)

The gas flow channel 10 is defined by the crystal growth section 6 with a cylindrical shape body. The gas flow channel 10 includes a first flow channel 10A, a second flow channel 10B, and a connection portion 10C. As depicted in FIG. 1, the first flow channel 10A is disposed surrounding the spraying orifice of the raw material gas nozzle 8 and the spraying orifices of the reactive gas nozzles 9, and has a first opening 10A1. The second flow channel 10B is disposed on the downstream side of the first flow channel 10A and has a second opening 10B1. The first flow channel 10A and the second flow channel 10B are connected to each other by the connection portion 10C between the first opening 10A1 and the second opening 10B1. The second opening 10B1 is configured to have an area larger than that of the first opening 10A1, and the connection portion 10C is configured such that the width thereof is gradually increased from the first opening 10A1 toward the second opining part 10B1. Both of the first flow channel 10A and the second flow channel 10B have a cylindrical shape in this embodiment, but they are not limited to this, and may have other shapes. The connection portion 10C can have a shape that expands at a constant angle with respect to the distance away from the first opening 10A1 in the side view. The connection portion 10C has a tapered shape depicted in FIG. 1 in this embodiment, but it is not limited to this. For example, the connection portion may have other shapes such as a curbed line shape or a step-like shape in the side view. At the connection position between the connection portion 10C and the second flow channel 10B, the angle a formed by the inner wall surface of the connection portion 10C and the plane of the second opening 10B1 is not limited to, but preferably is more than 0 degree and smaller than 90 degrees, and more preferably is in a range from 30 degrees to 60 degrees.

The connection position between the first flow channel 10A and the connection portion 10C is not limited to, but can be located above the upper face 12a of the substrate supporting member 12. In this embodiment, the difference between the vertical distance from the front end of the spraying orifice of the raw material gas nozzle 8 to the upper face 12a of the substrate supporting member 12 and the vertical distance from the front end of the spraying orifice of the raw material gas nozzle 8 to the plane of the second opening 10B1 is preferably within 30% and more preferably within 10% of the vertical distance from the front end of the spraying orifice of the raw material gas nozzle 8 to the upper face 12a of the substrate supporting member 12.

The difference between the area acquired by subtracting the area of the upper face 12a of the substrate supporting member from the area of the second opening 10B1 and the area of the first opening 10A1 is not limited to, but is preferably within 50% and more preferably within 10% of the area of the first opening 10A1. In this manner, the gas flow channel 10 forms a gas flow path through which the gases sprayed from the raw material gas nozzle and the reactive gas nozzles flow in the reaction container 20. By keeping the ratio of the cross-sectional area of the flow pass in the first flow channel 10A on the upstream side of the gas flow path to that of the flow pass in the second flow channel 10B, the group-III element-containing gas and the reactive gas flow at a constant flow rate in the gas flow path formed by the gas flow channel 10, thereby the backward flow of gases can be suppressed, and the adhesion of sediments including group-III compound semiconductor crystals to the inner wall surface of the manufacturing apparatus 1 can be suppressed.

The difference between the area of the first opening 10A1 and the area of the upper face 12a of the substrate supporting member is not limited to, but is preferably within 30% and is more preferably within 10% of the area of the upper face 12a of the substrate supporting member. By keeping the ratio of the area of the first opening 10A1 and the area of the upper surface 12a of the substrate holding member constant, the group-III element-containing gas sprayed from the raw material gas nozzle 8 and the reactive gas sprayed from the reactive gas nozzles 9 in the first flow channel 10A flow in the gas flow path formed by the gas flow channel 10, and are conveyed onto the seed substrate 11 without spreading around, and thud the utilization efficiency of the gases can be improved.

For the material of the gas flow channel 10, for example, ceramic such as quartz, carbon, SiC-coated carbon, PG-coated carbon, PBN-coated carbon, SiC, or molybdenum, iron, cobalt, nickel, or an alloy containing any of the above as the main component, can be used.

The group-III element-containing gas and the reactive gas flowing in the gas flow path formed by the gas flow channel 10 are mixed with each other in the mixing region S1. The mixing region S1 is not limited to, but can be located at a position above the surface of the seed substrate 11 toward the raw material gas nozzle 8. The mixed raw material gases react on the seed substrate 11 in the growth region S2 and a group-III compound semiconductor crystal is grown thereon. The mixing region S1 and the growth region S2 are maintained at a desired temperature to promote the reaction of the mixed raw material gases. In this embodiment, a second heater 15 of the heating element is disposed on the outer circumferential portion of the mixing region S1 and the growth region S2. Preferably the temperature of the second heater 15 is maintained at 900° C. or higher and 1,400° C. or lower for the growth of the group-III compound semiconductor crystal.

According to the above configuration, the utilization efficiency of the raw material gas can be improved by increasing the transportation e efficiency of the raw material gas to the seed substrate 11, and the adhesion of sediments to the inner wall surface of the manufacturing apparatus 1 can be suppressed. The production yield of the group-III compound semiconductor crystals can thereby be improved.

### EXAMPLE 1

In Example 1, the conditions for the manufacturing method of GaN, which is one of the group-III compound semiconductor crystals according to the embodiment of the present disclosure, were specifically designed as below, and a GaN crystal was grown on the seed substrate 11 in the manufacturing apparatus 1 depicted in FIG. 1. A thermo-fluid analysis was conducted by computer aided engineering (CAE) under the same manufacture conditions.

The inner diameter of the first flow channel 10A and the outer diameter of the substrate supporting member 12 were both set to be 120 mm. The inner diameter of the second flow channel 10B was set to be 170 mm. The angle a formed by the inner wall surface of the connection portion 10C and the plane of the second opening 10B1 was set to be 45 degrees. The second opening 10B1 was disposed at the same height as the surface of the substrate supporting member 12. The inner diameter of the raw material gas nozzle 8 was set to be 50 mm. The number of the disposed reactive gas nozzles 9 was eight and the inner diameters of all thereof were set to be 5 mm. The inclination angle θa was set to be 45 degrees with respect to the downward vertical direction and the deflection angle Ob was arranged such that in the planar view in FIG. 2B, each of the reactive gas nozzles 9 was directed in the radial direction when the reactive gas nozzle 9 self-rotated counterclockwise (in the direction A depicted in FIG. 2B) by 10 degrees. The distance from the front end of the raw material gas nozzle 8 to the surface of the seed substrate 11 was set to be 100 mm. A GaN single crystal having a diameter of 100 mm was used as the seed substrate 11.

The growth conditions were as follows. A piece of metal Ga was placed in the raw material container 3 as the starting Ga source. Under a pressure of 1.0×10⁵ Pa, H₂O gas produced from 5 SLM of H₂ gas and 20 SCCM of O₂ gas was introduced from the reactive gas supply pipe 7 to produce Ga₂O gas as the raw material gas. The produced raw material gas Ga₂O was sprayed from the raw material gas nozzle 8 toward the GaN single crystal substrate in the crystal growth section. 5 SLM of H₂ gas and 3 SLM of N₂ gas were discharged from the separate gas discharge outlets disposed on the outer circumference of the raw material gas nozzles 8. On the other hand, nitrogen element-containing gases NH₃ and N₂ gas were used as the reactive gas. Under a pressure of 1.0×10⁵ Pa, 1 SLM of NH₃ gas and 9 SLM of N₂ gas were introduced and were sprayed from the reactive gas nozzles 9 toward the GaN single crystal substrate. 10 SLM of H₂ gas and 20 SLM of N₂ gas were discharged from the separate gas discharge outlets disposed on the inner or the outer circumference of the reactive gas nozzles 9. The electric power for each of the first heater 14 and the second heater 15 in the outer circumferential portion of the reaction container 20 was supplied such that the temperature of the first heater 14 was maintained at 1,150° and that of the second heater 15 was maintained at 1,200° C. The substrate supporting member 12 was rotated at 1,000 RPM.

### EXAMPLE 2

In Example 2, a crystal of GaN was grown on the seed substrate 11 under the same conditions as those in Example 1 except the fact that the angle a formed by the inner wall surface of the connection portion 10C and the plane of the second opening 10B1 in the side view in FIG. 1 was set to be 30 degrees and 60 degrees, respectively. A thermo-fluid analysis was conducted by CAE under the same manufacture conditions.

### EXAMPLE 3

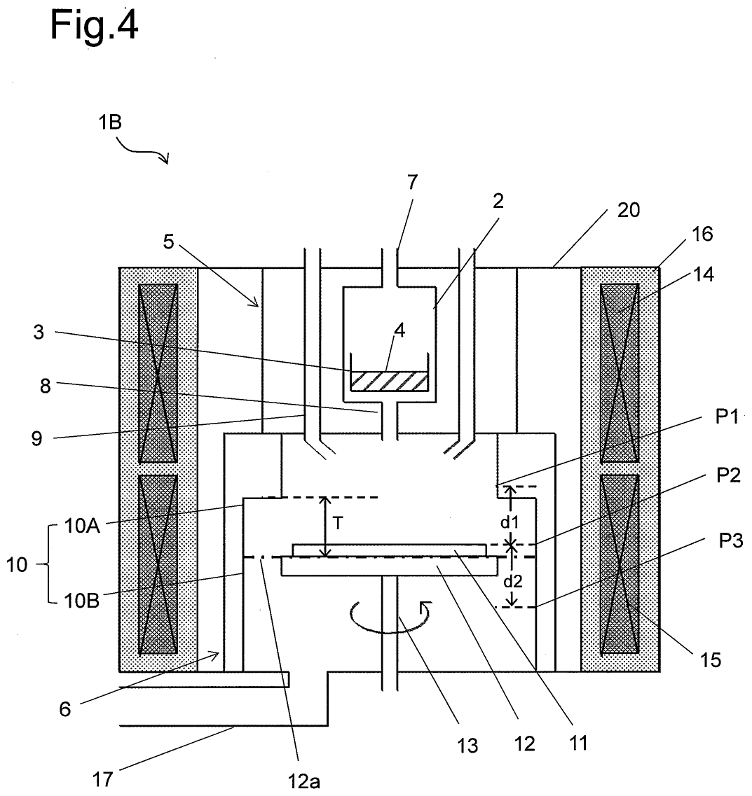

In example 3, a crystal of GaN was grown on the seed substrate 11 under the same conditions as those in Example 1 except the fact that, assuming that the vertical direction from the substrate supporting member 12 toward the raw material gas nozzle 8 shown in in FIG. 1 was positive, then the position of the second opening 10B1 (a vertical distance T from the second opening 10B1 to the upper face 12a of the substrate supporting member 12 as depicted in FIG. 4, but not depicted in FIG. 1) was set to be −15 mm and +15 mm relative to that of Example 1, respectively. A thermo-fluid analysis was conducted by CAE under the same manufacture conditions.

### COMPARATIVE EXAMPLE 1

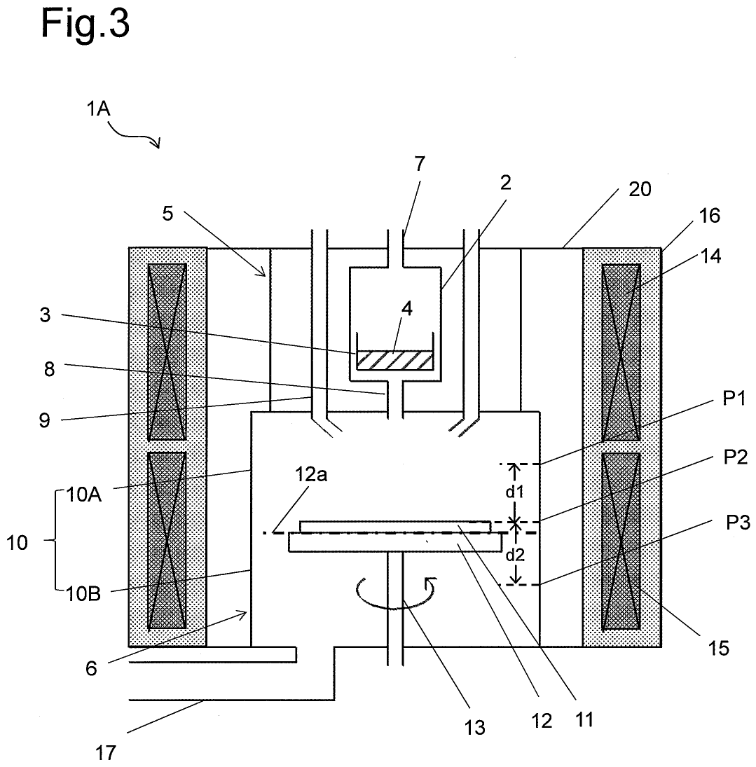

FIG. 3 is a schematic cross-sectional diagram depicting the configuration of a manufacturing apparatus 1A of a group-III compound semiconductor crystal according to Comparative Example 1 of the present disclosure. In comparison with Example 1, in Comparative Example 1, a crystal of GaN was grown on the seed substrate 11 under the same conditions as those in Example 1 except the fact that the inner diameter of the first flow channel 10A and the inner diameter of the second flow channel 10B had a same size which was set to be 170 mm. A thermo-fluid analysis was conducted by CAE under the same manufacture conditions.

### REFERENCE EXAMPLE 1

FIG. 4 is a schematic cross-sectional diagram depicting the configuration of a manufacturing apparatus 1B of a group-III compound semiconductor crystal according to Reference Example 1 of the present disclosure. In comparison with Example 1, in Reference Example 1, a crystal of GaN was grown on the seed substrate 11 under the same conditions as those in Example 1 except the fact that the angle a formed by the inner wall surface of the connection portion 10C and the plane of the second opening 10B1 was set to be 0 degree. A thermo-fluid analysis was conducted by CAE under the same manufacture conditions.

In each of Examples 1 to 3, Comparative Example 1, and Reference Example 1, the thermo-fluid analysis was conducted to evaluate the adhesion rate of sediments including group-III compound semiconductor crystals to the inner wall surface of the gas flow channel 10, the growth rate of GaN on the GaN single crystal substrate, and the in-plane distribution of the growth rate. The adhesion rate of sediments to the inner wall surface of the gas flow channel 10 was evaluated at three points of heights P1, P2, and P3 depicted in FIGS. 1, 3, and 4, respectively. P2 denoted the location of the inner wall surface of the gas flow channel 10 at a height equal to that of the upper face 12a of the substrate supporting member 12. Taking the vertical direction from the substrate supporting member 12 toward the raw material gas nozzle 8 as the positive direction, P1 and P3 denoted the location of the inner wall surface of the gas flow channel 10 at the heights separated from P2 by 35 mm (d1) and −35 mm (d2), respectively. The adhesion rate of sediments at each of the three points was determined by taking the average value of the values acquired at four points located in the circumferential direction at the same level. The in-plane distribution of the growth rate of the GaN crystal grown on the GaN single crystal substrate was determined by taking the value acquired by diving the standard deviation by the average value.

Table 1 shows the evaluation results for Example 1 and Comparative Example 1. As shown in Table 1, the adhesion rate of sediments to the inner wall surface of the gas flow channel 10 decreased in the order of the value at P3, P2, and P1, that is, decreasing toward the upstream side. It was found that the adhesion rate of sediments at P1 on the inner wall surface of the gas flow channel 10 located on the upstream of the seed substrate 11 in Example 1 was four times slower compared to that of Comparative Example 1. The in-plane distribution of the growth rate of the GaN crystal on the seed substrate 11 in Comparative Example 1 had a higher value as about 1.7 times as that of Example 1.

TABLE 1

| | | | | GaN Crystal on | |
|---|---|---|---|---|---|
| | Adhesion Rate of Sediments | | | Seed Substrate | |
| | deposit on Inner Wall | | | | In-Plane |
| | surface of Flow Channel | | | Growth | Distribution |
| | P1 | P2 | P3 | Rate | of Growth |
| | (μm/h) | (μm/h) | (μm/h) | (μm/h) | Rate (%) |
| Example 1 | 0.96 | 4.53 | 8.89 | 55.4 | 15.2 |
| Comparative | 3.75 | 5.29 | 8.36 | 79.4 | 26.4 |
| Example 1 | | | | | |

Since the adhesion of sediments to the inner wall surface of the gas flow channel 10 on the upstream side of the seed substrate 11 most significantly involve in the mixing of particles from the sediments into the group-III compound semiconductor crystal on the seed substrate 11, the slower the adhesion rate of sediments at P1 located on the upstream side of the seed substrate 11, the less the particles mix into the group III compound semiconductor crystal. The in-plane distribution of the growth rate of the GaN crystal on the seed substrate 11 is a parameter that indicates the uniformity of the GaN crystal growth on the seed substrate 11. That is, the lower the value of the in-plane distribution of the growth rate, the more uniformly the GaN crystal grows on the seed substrate 11. From the results shown in Table 1, it was confirmed that compared to Comparative Example 1, the generation of the sediment on the upstream side of the seed substrate 11 was more suppressed, and the GaN crystal was more uniformly grown on the seed substrate 11 in Example 1.

Table 2 shows the evaluation results of Examples 1, 2, Reference Example 1, and Comparative Example 1. From the results shown in Table 2, it was found that, compared to the result of Comparative Example 1, excellent results were acquired in all of Examples 1, 2, as well as Reference Example 1 for both of the adhesion rate of sediments at P1 on the inner wall surface of the flow channel 10 located on the upstream side of the seed substrate 11 and the in-plane distribution of the growth rate of GaN on the seed substrate 11. It was confirmed that, in Example 1, the generation of the sediments on the upstream side of the seed substrate 11 was suppressed and the GaN crystal was more uniformly grown on the seed substrate 11.

TABLE 2

| | | | | | GaN Crystal on | |
|---|---|---|---|---|---|---|
| | | Adhesion Rate of Sediments deposit | | | Seed Substrate | |
| | | on Inner Wall surface of Flow Channel | | | | In-Plane |
| | Gas Induction | P1 | P2 | P3 | Growth Rate | Distribution of |
| | Section | (μm/h) | (μm/h) | (μm/h) | (μm/h) | Growth Rate (%) |
| Example 1 | α = 45 degrees | 0.96 | 4.53 | 8.89 | 55.4 | 15.2 |
| Example 2 | α = 30 degrees | 0.65 | 6.79 | 9 | 54.9 | 16.1 |
| | α = 60 degrees | 2.77 | 4.73 | 8.81 | 55.6 | 15.2 |
| Reference | α = 0 degrees | 1.91 | 5.63 | 8.56 | 55.1 | 15.4 |
| Example 1 | | | | | | |
| Comparative | | 3.75 | 5.29 | 8.36 | 79.4 | 26.4 |
| Example 1 | | | | | | |

Table 3 shows the evaluation results for Example 1 and Example 3. From the results shown in Table 3, it was found that the adhesion rate of sediments at P1 of the inner wall surface of the flow channel 10 became lower as the position (T) of the second opening 10B1 became lower. It was confirmed that, when the position (T) of the second opening 10B1 was −15 mm, the adhesion rate of sediments at P2 on the inner wall surface of the flow channel 10 was remarkably higher than that of Example 1, while the growth rate of the GaN crystal on the seed substrate 11 was slightly slowed down, and the in-plane distribution of the growth rate was slightly higher.

TABLE 3

| | | | | | | GaN Crystal on | |
|---|---|---|---|---|---|---|---|
| | | | Adhesion Rate of Sediments deposit | | | Seed Substrate | |
| | Location of | | on Inner Wall surface of Flow Channel | | | | In-Plane |
| | Second Opening | | P1 | P2 | P3 | Growth Rate | Distribution of |
| | T | | (μm/h) | (μm/h) | (μm/h) | (μm/h) | Growth Rate (%) |
| Example 1 | 0 | mm | 0.96 | 4.53 | 8.89 | 55.4 | 15.2 |
| Example 3 | 15 | mm | 2.01 | 4.02 | 8.73 | 55.3 | 15.3 |
| | −15 | mm | 0.75 | 11.54 | 7.08 | 55.1 | 15.5 |

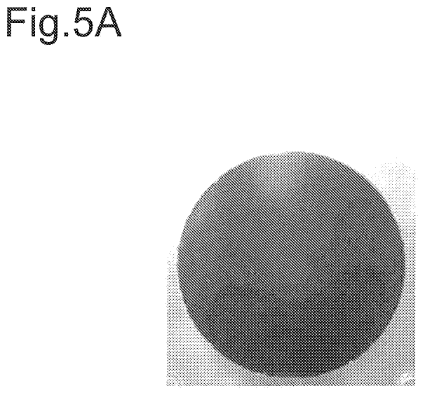

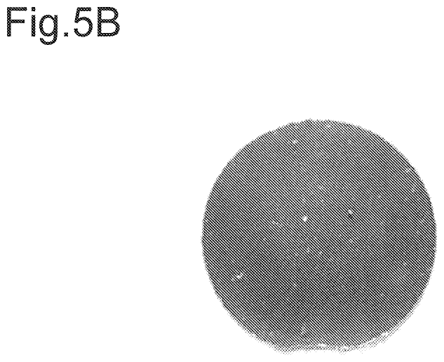

FIG. 5A is a photograph of an outer appearance of a GaN substrate grown on the seed substrate according to Example 1, and FIG. 5B is a photograph of an outer appearance of the GaN substrate grown on the seed substrate according to Comparative Example 1. The number of pits and through-holes on the surface of the grown GaN was nine in FIG. 5A, and 60 in FIG. 5B, respectively. It is presumed that this was caused by the deposition adhering to the inner wall surface of the flow channel 10 became particles and mixed into the GaN film on the GaN single crystal substrate. That is, it was confirmed that by suppressing the adhesion of sediments to the inner wall surface of the flow channel on the upstream side of the surface of the GaN single crystal substrate, the mixing of particles into the grown GaN film was suppressed and the pits and the through-holes on the surface of the grown GaN were reduced.

The present disclosure is not limited to the above embodiment, various modifications can be made within the scope of the claims, and embodiments obtained by appropriately combining the technical means disclosed in different embodiments are also included in the technical scope of the present disclosure.

According to the manufacturing apparatus for a group-III compound semiconductor crystal of the present disclosure, generation of sediments on the inner wall surface of the apparatus on the upstream side of the seed substrate can be suppressed, and mixing of particles into the group-III compound semiconductor crystal growing on the seed substrate can be suppressed. The production yield of a group-III compound semiconductor crystal can thereby be improved.

A group-III compound semiconductor crystal obtained by the manufacturing apparatus for a group-III compound semiconductor crystal according to the present disclosure can be used in, for example, optical devices such as light emitting diodes or laser diodes, electronic devices such as rectifiers or bipolar transistors, or semiconductor sensors such as temperature sensors, pressure sensors, radiation sensors, or visible-ultraviolet detectors. The present disclosure is not limited to being used in the above, and is applicable to a wide range of fields.
1 manufacturing apparatus for a group-III compound semiconductor crystal
2 raw material reaction chamber
3 raw material container
4 starting Ga source
5 raw material reaction section
6 crystal growth section
7 reactive gas supply pipe
8 raw material gas nozzle
9 reactive gas nozzle
10 gas flow channel
10A first flow channel
10B second flow channel
10C connection portion
11 seed substrate
12 substrate supporting member
13 rotating shaft
14 first heater
15 second heater
16 heating element
17 gas outlet
20 reaction container
S1 mixing region
S2 crystal growth region

What is claimed is:

1. A manufacturing apparatus for a group-III compound semiconductor crystal, the manufacturing apparatus comprising
a reaction container, wherein
the reaction container comprises:
a raw material reaction section;
a crystal growth section; and
a gas flow channel, wherein
the raw material reaction section comprises:
a raw material reaction chamber that produces therein group-III element-containing gas; and
a raw material gas nozzle that leads the produced group-III element-containing gas out of the raw material reaction chamber, and sprays the produced group-III element-containing gas toward the crystal growth section, wherein
the crystal growth section comprises:
a substrate supporting member that holds a seed substrate on an upper face thereof and rotates the seed substrate, on which a group-III compound semiconductor crystal grows; and
reactive gas nozzles that spray reactive gases for reacting with the group-III element-containing gas to produce the group-III compound semiconductor crystal, wherein
the gas flow channel comprises:
a first flow channel which is disposed surrounding a spraying orifice of the raw material gas nozzle and spraying orifices of the reactive gas nozzles;
a second flow channel; and
a connection portion, wherein
the first flow channel comprises a first opening, wherein
the second flow channel comprise a second opening, wherein
an area of the second opening is configured to be larger than an area of the first opening, wherein
the connection portion connects the first opening and the second opening with each other, wherein
the gas flow channel forms a gas flow path in which the gases sprayed from both of the raw material gas nozzle and the reactive gas nozzles flow in the reaction container sequentially passing through the first flow channel, the connection portion, and the second flow channel, and wherein
the substrate supporting member is disposed inside the gas flow path and located on the downstream side of the first opening.

2. The manufacturing apparatus for a group-III compound semiconductor crystal according to claim 1, wherein
the connection portion is comprised of a tapered shape expending from the first opening toward the second opening.

3. The manufacturing apparatus for a group-III compound semiconductor crystal according to claim 1, wherein
the substrate supporting member is disposed on the downstream side of the second opening.

4. The manufacturing apparatus for a group-III compound semiconductor crystal according to claim 1, wherein
a difference between the area of the first opening and the area of the upper face of the substrate supporting member is within 30% of the area of the upper face.

5. The manufacturing apparatus for a group-III compound semiconductor crystal according to claim 1, wherein
a difference between an area acquired by subtracting the area of the upper face of the substrate supporting member from the area of the second opening and the area of the first opening is within 50% of the area of the first opening.

6. The manufacturing apparatus for a group-III compound semiconductor crystal according to claim 1, wherein
the first flow channel and the second flow channel are each configured to have a cylindrical shape, and wherein
a difference between a vertical distance from the raw material gas nozzle to the upper face of the substrate supporting member and a vertical distance from the spraying orifice of the raw material gas nozzle to the second opening is within 30% of a vertical distance from the raw material gas nozzle to the upper face.

7. The manufacturing apparatus for a group-III compound semiconductor crystal according to claim 1, wherein
the raw material gas nozzle is disposed such that a spraying direction of the spraying orifice thereof is directed toward the upper face of the substrate supporting member.

8. The manufacturing apparatus for a group-III compound semiconductor crystal according to claim 1, wherein
the reactive gas nozzles are disposed such that spraying directions of the spraying orifices thereof are inclined with respect to the upper face of the substrate supporting member.

9. The manufacturing apparatus for a group-III compound semiconductor crystal according to claim 1, wherein
the reactive gas nozzles are disposed such that the spraying directions of the spraying orifices thereof above the upper face of the substrate supporting member are deflected with respect to the radial direction of the rotation of the seed substrate.
